(19) United States
(12) Patent Application Publication
(10) Pub. No.: US 2024/0260326 A1
(43) Pub. Date: Aug. 1, 2024

(54) DISPLAY DEVICE

(71) Applicant: LG Display Co., Ltd., Seoul (KR)

(72) Inventors: KyooHo LEE, Paju-si (KR); JaeYoung OH, Paju-si (KR)

(21) Appl. No.: 18/406,032

(22) Filed: Jan. 5, 2024

(30) Foreign Application Priority Data
Jan. 26, 2023 (KR) 10-2023-0010014

(51) Int. Cl. H10K 59/122; H10K 59/38; H10K 59/80

(52) U.S. Cl. CPC H10K 59/122; H10K 59/38; H10K 59/879

(57) ABSTRACT

Embodiments of the disclosure relate to a display device. The device includes a first substrate including at least one of red, green, and blue subpixels. The device includes a light emitting element including a first electrode, a light emitting layer, and a second electrode. The device includes a first bank having an opening exposing at least a portion of the first electrode, a first lens part on the second electrode and having a first lens including a low-refractive material corresponding to the opening, a high-refractive layer on the first bank and the first lens part and including a high-refractive material, a light conversion layer on the high-refractive layer and including a quantum dot converting light of a color corresponding to each of the red, green, and blue subpixels. The device includes a color filter layer disposed on the light conversion layer, thereby blocking light propagating to adjacent pixels.

### CROSS-REFERENCE TO RELATED APPLICATION

This application claims priority from Korean Patent Application No. 10-2023-0010014, filed on Jan. 26, 2023, which is hereby incorporated by reference for all purposes as if fully set forth herein.

### BACKGROUND

### Technical Field

Embodiments of the present disclosure relate to a display device.

### Description of the Related Art

Display devices are widely used as display screens for laptop computers, tablet computers, smartphones, portable display devices, and portable information devices, as well as for televisions or monitors.

Display devices may be divided into reflective display devices and emissive display devices. The reflective display device is a display device that displays information by reflecting natural light or light from an external light source of the display device to the display device. The emissive display device is a display device that displays information by using the light generated from light emitting elements or a light source embedded in the display device.

### BRIEF SUMMARY

The conventional display device has the adjacent pixel emission issue that arises as the light emitted from a light emitting element is guided and leaks to the adjacent pixel due to multiple transparent layers disposed between the light emitting element and the light conversion layer including quantum dots.

Embodiments of the present disclosure may provide a display device capable of blocking light propagation to the adjacent pixel by including a low-refractive index structure and a high-refractive index structure between the light emitting element and the light conversion layer.

Embodiments of the present disclosure may provide a display device capable of enhancing light extraction efficiency by blocking light propagation to the adjacent pixel.

Embodiments of the present disclosure may provide a display device capable of low power consumption by blocking light propagation to the adjacent pixel.

Embodiments of the present disclosure may provide a display device comprising a first substrate including at least one of red, green, and blue subpixels, a light emitting element including a first electrode disposed on the first substrate, a light emitting layer disposed on the first electrode, and a second electrode disposed on the light emitting layer, a first bank having an opening exposing at least a portion of the first electrode, a first lens part disposed on the second electrode and having a first lens including a low-refractive material corresponding to the opening, a high-refractive layer disposed on the first bank and the first lens part and including a high-refractive material, a light conversion layer disposed on the high-refractive layer and including a quantum dot converting light of a color corresponding to each of the red, green, and blue subpixels, and a color filter layer disposed on the light conversion layer and having a color corresponding to each of the red, green, and blue subpixels.

According to embodiments of the present disclosure, there may be provided a display device capable of blocking light propagation to the adjacent pixel.

According to embodiments of the present disclosure, there may be provided a display device capable of enhancing light extraction efficiency by blocking light propagation to the adjacent pixel.

According to embodiments of the present disclosure, there may be provided a display device capable of low power consumption by blocking light propagation to the adjacent pixel.

### BRIEF DESCRIPTION OF THE SEVERAL VIEWS OF THE DRAWINGS

The above and other objects, features, and advantages of the present disclosure will be more clearly understood from the following detailed description, taken in conjunction with the accompanying drawings, in which:

FIG. 1 is a view illustrating a system configuration of a display device according to embodiments of the present disclosure;

FIGS. 2A, 2B, and 2C are cross-sectional views taken along line A-B of FIG. 1 to which a structure according to embodiments of the present disclosure applies;

FIG. 3A is a cross-sectional view taken along line A-B of FIG. 1 to which a structure according to embodiments of present the disclosure does not applies;

FIG. 3B is a view illustrating an emission defect in the structure illustrated in FIG. 3A; and

FIGS. 4, 5, 6, and 7 are cross-sectional views taken along line A-B of FIG. 1 to which another structure according to embodiments of the present disclosure applies.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure are described in detail with reference to the accompanying drawings.

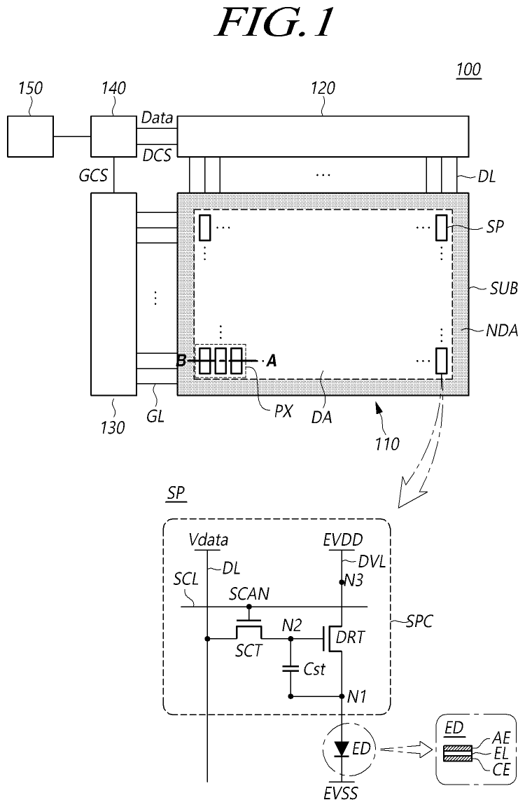

FIG. 1 is a view illustrating a system configuration of a display device 100 according to embodiments of the present disclosure.

Referring to FIG. 1, a display driving system of a display device 100 according to embodiments of the present disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display.

The display panel 110 may include a plurality of signal lines disposed on the substrate SUB. For example, the plurality of signal lines may include data lines DL, gate lines GL, driving voltage lines, and the like.

Each of the plurality of data lines DL is disposed to extend in a first direction (e.g., a column direction or a row direction), and each of the plurality of gate lines GL is disposed to extend in a direction crossing the first direction.

The display driving circuits may include a data driving circuit 120 and a gate driving circuit 130 and may further include a controller 140 for controlling the data driving circuit 120 and the gate driving circuit 130.

The data driving circuit 120 may output data signals (also referred to as data voltages) corresponding to an image signal to the plurality of data lines DL. The gate driving circuit 130 may generate gate signals and output the gate signals to the plurality of gate lines GL. The controller 140 may convert the input image data input from an external host 150 to meet the data signal format used in the data driving circuit 120 and supply the converted image data Data to the data driving circuit 120.

The data driving circuit 120 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

Referring to FIG. 1, in the display device 100 according to embodiments of the present disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

The light emitting element ED may include an anode electrode AE, a cathode electrode CE, and a light emitting layer EL positioned between the anode electrode AE and the cathode electrode CE. The anode electrode AE may be a pixel electrode involved in forming the light emitting element ED of each subpixel SP and may be electrically connected to the first node N1 of the driving transistor DRT. The cathode electrode CE may be a common electrode involved in forming the light emitting elements ED of all the subpixels SP, and a ground voltage EVSS may be applied thereto.

For example, the light emitting element ED may be an organic light emitting diode (OLED), an inorganic light emitting diode (LED), or a quantum dot light emitting element, which is a self-luminous semiconductor crystal.

The driving transistor DRT is a transistor for driving the light emitting element ED, and may include a first node N1, a second node N2, and a third node N3. The first node N1 may be a source node or a drain node, and may be electrically connected to the anode electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

The display device 100 according to embodiments of the present disclosure may have a top emission structure or a bottom emission structure. The top emission structure is described below as an example. For example, in the top emission structure, the anode electrode AE may be a reflective metal, and the cathode electrode CE may be a transparent conductive film.

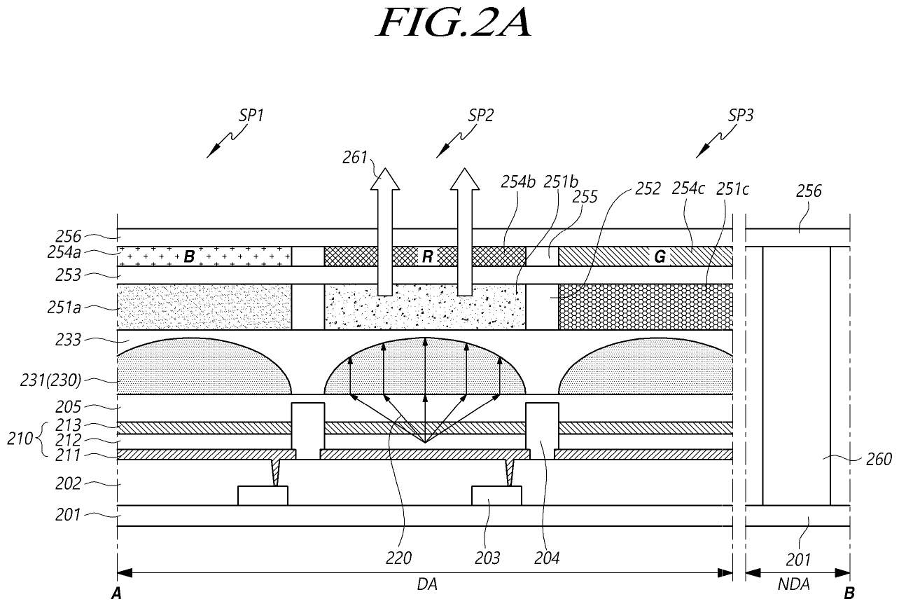

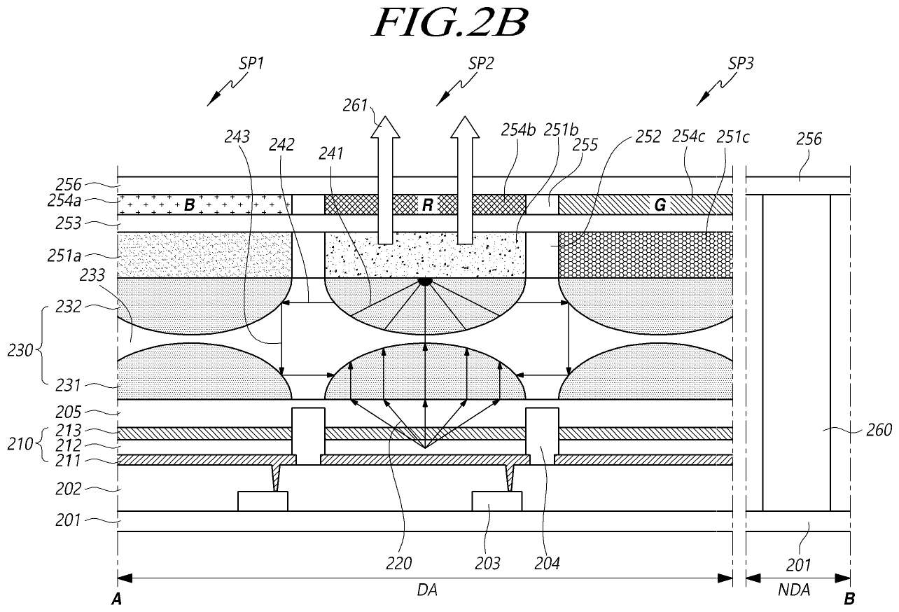

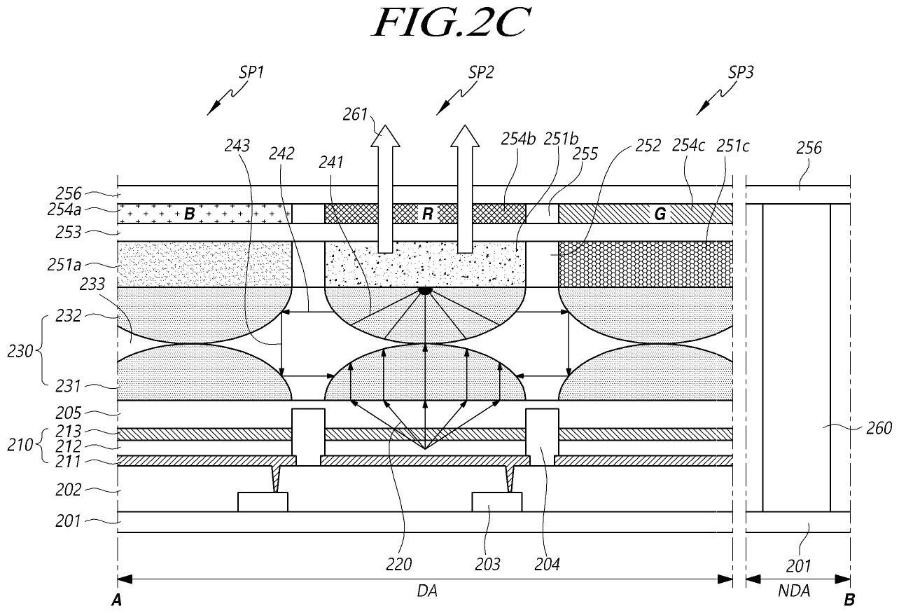

FIGS. 2A to 2C are cross-sectional views taken along line A-B of FIG. 1 to which a structure according to embodiments of the present disclosure applies.

Referring to FIGS. 2A to 2C, a display device 100 according to embodiments of the present disclosure may include a plurality of subpixels SP1, SP2, and SP3, a first substrate 201, a light emitting element 210, a first bank 204, a lens part 230, a high refractive layer 233, light conversion layer 251a, 251b, and 251c, and a color filter layer 254a, 254b, and 254c.

Referring to FIG. 2A, a display device 100 according to embodiments of the present disclosure may include a first substrate 201 including a plurality of subpixels SP1, SP2, and SP3, a light emitting element 210 including a first electrode 211, a light emitting layer 212, and a second electrode 213, a first bank 204 having an opening, a first lens part including a first lens 231, a high refractive layer 233, a light conversion layer 251a, 251b, and 251c, and a color filter layer 254a, 254b, and 254c.

The plurality of subpixels SP1, SP2, and SP3 may be arranged on the first substrate 201. The substrate 201 may include at least one of red, green, and blue subpixels.

The substrate 201 may be selected as a material for forming an element having excellent mechanical strength or dimensional stability. The substrate 201 may be not only a glass substrate, but also a plastic substrate including polyethylene terephthalate (PET), polyethylene naphthalate (PEN), polyimide, or the like.

A pixel driving circuit layer 202 including a thin film transistor 203 may be disposed on the first substrate 201.

The pixel driving circuit layer 202 may include at least one insulation film and at least two metal layers. The insulation film may be formed of at least one inorganic film or at least one organic film or may be formed of at least one inorganic film and at least one organic film.

The light emitting element 210 may be disposed on the pixel driving circuit layer 202. For example, the light emitting element 210 may be an organic light emitting diode (OLED), an inorganic light emitting diode (LED), or a quantum dot light emitting element, which is a self-luminous semiconductor crystal.

Described below is an example in which the light emitting element 210 is an organic light emitting diode (OLED), but the present disclosure is not limited thereto.

The light emitting element 210 may include a first electrode 211, a light emitting layer 212, and a second electrode 213. For example, the light emitting element 210 may emit a blue light. For example, the light emitting element 210 may emit a white light. For example, the light emitting element 210 may emit a light of color corresponding to the red subpixel, the blue subpixel, and the green subpixel.

The first electrode 211 is a pixel electrode serving as an anode, and may be independently disposed in each of the subpixels.

The first electrode 211 may include a reflective metallic material having a low work function and excellent reflection efficiency.

For example, the reflective metal included in the first electrode 211 may include any one selected from the group consisting of aluminum (Al), silver (Ag), copper (Cu), magnesium (Mg), platinum (Pt), gold (Au), nickel (Ni), neodymium (Nd), iridium (Ir), and chromium (Cr), or any one of alloys including at least one thereof.

For example, the first electrode 211 may be formed to be a multilayer structure of any one of a stacked structure (Ti/Al/Ti) of aluminum (Al) and titanium (Ti), a stacked structure (ITO/Al/ITO) of aluminum (Al) and ITO, an alloy of APC (Ag/Pd/Cu), and a stacked structure (ITO/APC/ITO) of APC alloy and ITO, or may be formed to be a single layer structure or a multilayer structure of at least one of aluminum (Al), silver (Ag), copper (Cu), magnesium (Mg), platinum (Pt), gold (Au), nickel (Ni), neodymium (Nd), iridium (Ir), chromium (Cr), and alloys thereof.

Further, the first electrode 211 may include a reflective electrode and a transparent electrode disposed on the reflective electrode. The reflective electrode may be the above-described reflective metal, and the transparent electrode may include transparent conductive oxide (TCO) such as indium tin oxide (ITO), indium Zinc oxide (IZO), indium gallium Zinc oxide (IGZO), or the like.

The light emitting layer 212 may be an organic light emitting layer. The organic light emitting layer may include multiple layers of a hole injection layer, a hole transport layer, a light emitting material layer, an electron transport layer, and an electron injection layer to increase light emission efficiency.

The second electrode 213 is a common electrode serving as a cathode, and may be commonly disposed in all subpixels SP1 to SP3.

The second electrode 213 may be a transflective electrode including a transflective metal or a transparent electrode.

The second electrode 213 may include any one selected from the group consisting of aluminum (Al), silver (Ag), copper (Cu), magnesium (Mg), platinum (Pt), gold (Au), nickel (Ni), chromium (Cr), titanium (Ti), tungsten (W), tantalum (Ta), cobalt (Co), iron (Fe), and molybdenum (Mo), or any one of alloys including at least one thereof.

The first bank 204 may be disposed on the pixel driving circuit layer 202.

The first bank 204 may define an opening overlapping the light emitting element 210. Further, the first bank 204 may define an opening by exposing at least a portion of the first electrode 211.

The first bank 204 may define an emission area of the display device 100, and thus may be referred to as a pixel defining film. The first bank 204 may be an organic insulation material. For example, the first bank 204 may be formed of a polyimide, acryl, or benzocyclobutene (BCB) resin, but is not limited thereto.

An encapsulation layer 205 in which a plurality of organic films and inorganic films are stacked may be further formed on the light emitting element 210 and the first bank 204.

The encapsulation layer 205 may be formed by alternately stacking a plurality of inorganic films and organic films. For example, the inorganic film may be formed of at least one of aluminum oxide (AlxOx), silicon oxide (SiOx), SiNx, SiON, and LiF to primarily block penetration of external moisture or oxygen, but is not limited thereto. The organic film may secondarily block the penetration of external moisture or oxygen. The organic film serves as a buffer for relieving stress between layers due to bending of the display device 100 and may also serve to enhance planarization performance. Such an organic film may be formed of a polymer material such as an acrylic resin, an epoxy resin, polyimide, or polyethylene, but is not limited thereto.

A first lens part including the first lens 231 may be disposed on the encapsulation layer 205.

The first lens 231 may be disposed to correspond to an opening partitioned by the first bank 204. The first lens 231 may be disposed to correspond to the emission area of each subpixel.

The first lens 231 may be a low-refractive lens having a refractive index of 1.5 or less. In some embodiments, the low-refractive material has a refractive index of 1.5 or less. In some embodiments, the low-refractive material includes an organic material including any one of acryl resin, epoxy resin, phenolic resin, polyamide resin, polyimide resin, or polyacrylate.

The first lens 231 may include a low-refractive material. For example, the first lens 231 may include an organic material such as an acryl resin, an epoxy resin, a phenolic resin, a polyamide resin, a polyimide resin, polyacrylate, or the like.

The first lens 231 may be manufactured by dropping a material containing a low-refractive material on the encapsulation layer 205 using an inkjet process and then curing the material. Further, the first lens 231 may be manufactured through an etching process using a mask by coating a low-refractive material on the encapsulation layer 205 and curing the low-refractive material.

The high-refractive layer 233 may be disposed on the encapsulation layer 205 and the first lens part including the first lens 231.

The high-refractive layer 233 may have a refractive index of 1.8 or more.

The high-refractive layer 233 may include a high-refractive material. For example, the high-refractive layer 233 may include an inorganic material such as silicon nitride (SiNx), silicon oxide (SiOx), silicon oxynitride (SiOxNy), or the like.

The high-refractive layer 233 may serve to protect the light conversion layer 251a, 251b, and 251c including quantum dots. The high-refractive layer 233 may be formed of an inorganic material to prevent the outgassing generated in the organic film from passing therethrough.

The high-refractive layer 233 may be formed by depositing a high-refractive material on the encapsulation layer 205 and the first lens 231. For example, after the high-refractive layer 233 are deposited on the encapsulation layer 205 and the first lens 231 disposed on the first substrate 201, the first substrate 201 may be bonded to the second substrate 256 including the light conversion layer 251a, 251b, and 251c and the color filter layer 254a, 254b, and 254c manufactured in a separate process.

Further, the high-refractive layer 233 may be formed by depositing a high-refractive material on the light conversion layer 251a, 251b, and 251c and the color filter layer 254a, 254b, and 254c. For example, after the high-refractive layer 233 is deposited on the light conversion layer 251a, 251b, and 251c disposed on the second substrate 256, the second substrate 256 may be bonded to the first substrate 201 including the encapsulation layer 205 and the first lens 231 manufactured in a separate process.

Referring to FIGS. 2B and 2C, a second lens part including the second lens 232 may be disposed on the high-refractive layer 233.

The second lens 232 may be disposed under the light conversion layer 251a, 251b, and 251c to face the first lens 231.

The second lens 232 may be a low-refractive lens having a refractive index of 1.5 or less. The refractive index of the first lens 231 and the refractive index of the second lens 232 may be the same.

The refractive index of the first lens 231 and the refractive index of the second lens 232 may be smaller than the refractive index of the high-refractive layer 233. The refractive index of the first lens 231 and the refractive index of the second lens 232 may be the same, and the refractive index of the first lens 231 and the refractive index of the second lens 232 may be smaller than the refractive index of the high-refractive layer 233.

The second lens 232 may include a low-refractive material. The second lens 232 may include the same material as the first lens 231. For example, the second lens 232 may include an organic material such as an acryl resin, an epoxy resin, a phenolic resin, a polyamide resin, a polyimide resin, polyacrylate, or the like.

The first lens 231 and the second lens 232 may have a convex lens shape. For example, the convex surface of the convex lens, which is the upper surface of the first lens 231, and the convex surface of the convex lens, which is the upper surface of the second lens 232, may come into contact with each other.

The shapes of the first lens 231 and the second lens 232 may be aspheric convex lens shapes. When the first lens 231 and the second lens 232 have an aspheric convex lens shape, the angle between the surface of the lens and the boundary surface with the high-refractive layer 233 may be 45 degrees, so that total reflection may easily occur.

Referring to FIG. 2B, convex surfaces of the first lens 231 and the second lens 232 may be disposed to be spaced apart from each other, and a high-refractive layer 233 filled with a high-refractive material may be disposed in a space between the first lens 231 and the second lens 232.

The second lens 232 may be manufactured by dropping a material containing a low-refractive material on the light conversion layer 251a, 251b, and 251c using an inkjet process and then curing the material. Further, the second lens 232 may be manufactured through an etching process using a mask by coating a low-refractive material on the light conversion layer 251a, 251b, and 251c and curing the low-refractive material.

Referring to FIG. 2C, convex surfaces of the first lens 231 and the second lens 232 may contact each other, and a high-refractive layer 233 filled with a high-refractive material may be disposed in a space between the first lens 231 and the second lens 232.

The structure illustrated in FIGS. 2B and 2C may be manufactured by bonding the first substrate 201 having the first lens 231 and the high-refractive layer 233 and the second substrate 256 having the second lens 232, or bonding the first substrate 201 having the first lens 231 and the second substrate 256 having the second lens 232 and the high-refractive layer 233. The first and second substrates may be bonded with the convex surfaces of the first lens 231 and the second lens 232 spaced apart from each other as shown in FIG. 2B, or with the convex surfaces of the first lens 231 and the second lens 232 contacting each other as shown in FIG. 2C.

Referring to FIGS. 2A to 2C, the light 220 emitted from the red subpixel SP2 may travel in a straight line while passing through the first lens 231.

Referring to FIG. 2A, light passing through the first lens 231 and traveling in a straight line may be incident on the light conversion layer 251b as it is.

Referring to FIGS. 2B and 2C, the second lens 232 condenses light incident in a straight line, and the condensed light 241 is incident on the light conversion layer 251b.

In this case, the light 242 emitted from the low-refractive second lens 232 through the side surface may be totally reflected at the boundary between the high-refractive layer 233 and the low-refractive second lens 232, and the totally reflected light 243 may be directed to the first lens 231, blocking the light directed to the adjacent pixel on the side.

The light conversion layer 251a, 251b, and 251c may be disposed on the high-refractive layer 233.

The light conversion layer 251a, 251b, and 251c may convert light output from the light emitting element 210 into light of the color corresponding to each subpixel. The light conversion layer 251a, 251b, and 251c may include quantum dots that convert light of the color corresponding to each subpixel.

The light conversion layer 251a, 251b, and 251c may include quantum dots of different sizes or types to convert light of the color corresponding to each subpixel.

The types of quantum dots included in the light conversion layer 251a, 251b, and 251c are not particularly limited. The light conversion layer may include quantum dots of a single layer structure including one or more of group III-V semiconductor nanocrystals and group II-VI semiconductor nanocrystals or quantum dots of a multilayer structure having a core/shell structure.

Quantum dots are nanoparticles and feature photoluminescence (PL) in which electrons excited to a high energy level by external light emit light while returning to a low energy level. This feature of quantum dots may be utilized to convert the wavelength of light emitted from the light source of the display device. In particular, since quantum dots emit light having different wavelengths depending on the diameter, the quantum dots may be applied to manufacture a display device having high color purity by precisely controlling the diameter in the manufacturing process of the quantum dots.

The light conversion layers 251a, 251b, and 251c may be partitioned by a second bank 252, and the partitioned light conversion layers respectively correspond to the subpixels.

The second bank 252 may be disposed to overlap the first bank 204. The second bank 252 may be disposed between the respective light conversion layers 251a, 251b, and 251c of subpixels to correspond to the position where the first bank 204 is disposed.

The second bank 252 may include the same material as the first bank 204. For example, the second bank 252 may be an organic insulation material, and may be formed of polyimide, acryl, or benzocyclobutene (BCB)-based resin, but is not limited thereto.

A quantum dot protection layer 253 may be disposed on the light conversion layer 251a, 251b, and 251c.

It is necessary to prevent damage to the light conversion layer 251a, 251b, and 251c including quantum dots during the manufacturing process or during use after manufacturing. For example, it is necessary to prevent the outgassing generated from the color filter layer 254a, 254b, and 254c from damaging quantum dots included in the light conversion layer 251a, 251b, and 251c, thereby preventing the quantum dots from failing to convert the light output from the light emitting element into the first light, the second light, or the third light.

To that end, the quantum dot protection layer 253 may be interposed between the light conversion layer 251a, 251b, and 251c and the color filter layer 254a, 254b, and 254c.

The quantum dot protection layer 253 may be formed of an inorganic material such as silicon nitride (SiNx), silicon oxide (SiOx), silicon oxynitride (SiOxNy), or the like to prevent outgassing from passing therethrough. The quantum dot protection layer 253 may be formed of a single layer or multiple layers.

The color filter layer 254a, 254b, and 254c may be disposed on the quantum dot protection layer 253.

The color filter layers 254a, 254b, and 254c may be disposed to correspond to the subpixels SP1, SP2, and SP3, respectively. For example, the blue (B) color filter layer 254a may be disposed in the blue (B) subpixel SP1, and the red (R) color filter layer 254b and the green (G) color filter layer 254c may be disposed in the red (R) subpixel SP2 and the green (G) subpixel SP3, respectively.

The color filter layers 254a, 254b, and 254c may be partitioned by a black matrix 255 so that the partitioned color filter layers 254a, 254b, and 254c respectively correspond to the subpixels to prevent color mixing between the subpixels.

The black matrix 255 may be disposed to overlap the second bank 252. The black matrix 255 may be disposed between the respective color filter layers 254a, 254b, and 254c of the subpixels to correspond to the position where the second bank 252 is disposed.

The black matrix 255 may include at least one selected from among carbon black, black pigment, black dye, black resin, graphite powder, gravure ink, black spray, black enamel, or the like.

Further, the black matrix 255 may be formed by stacking patterns of color filters.

The second substrate 256 may be disposed on the color filter layer 254a, 254b, and 254c.

The second substrate 256 may transmit light, e.g., light 261. The second substrate 256 may be at least one of a transparent glass substrate, a transparent plastic substrate, and a transparent film, but is not limited thereto.

A sealing member 260 for sealing the first substrate 201 and the second substrate 256 may be disposed.

The display device 100 may be formed by bonding the first substrate 201 and the second substrate 256 by the sealing member 260. The sealing member 260 may be formed to surround the first substrate 201 and the second substrate 256 along the outer surfaces thereof to bond the first substrate 201 and the second substrate 256 together.

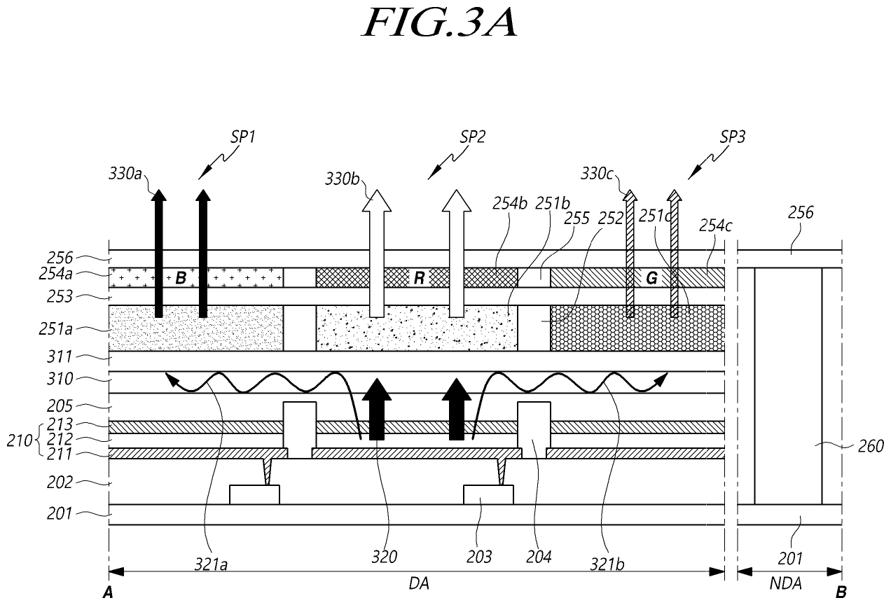

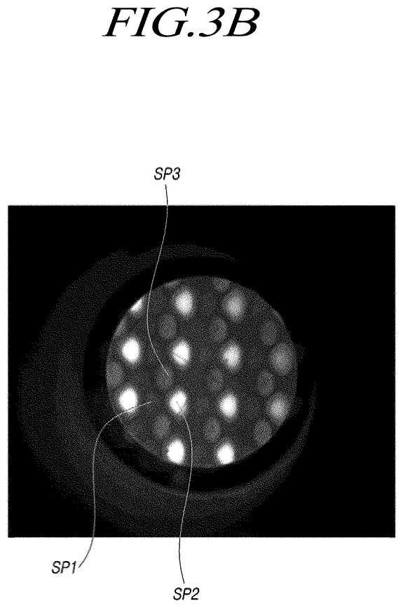

FIG. 3A is a cross-sectional view taken along line A-B of FIG. 1 to which a structure according to embodiments of the present disclosure does not applies. FIG. 3B is a view illustrating an emission defect in the structure illustrated in FIG. 3A. What is identical or similar to those described in connection with FIGS. 1 to 2C may be omitted or briefly described below.

Referring to FIG. 3A, in the conventional display device, the upper substrate 256 including the light conversion layer 251a, 251b, and 251c and the color filter layer 254a, 254b, and 254c, and the lower substrate 201 including the light emitting element 210 and the thin film transistor 203 are manufactured by separate processes, and then the upper substrate 256 and the lower substrate 201 are bonded together.

In this case, a plurality of layers are present between the light emitting element 210 and the light conversion layer 251a, 251b, and 251c. For example, various layers such as the encapsulation layer 205 on the light emitting element 210, the organic buffer layer 310 on the encapsulation layer 205, and the first quantum dot protection layer 311 on the organic buffer layer 310 are included, and these layers are configured as transparent layers to allow light of the light emitting element 210 to be emitted upward.

Referring to FIG. 3A, due to the plurality of transparent layers disposed between the light emitting element 210 and the light conversion layer 251a, 251b, and 251c, light may leak to adjacent pixels as the result of the light guide effect of light 320 output from the light emitting element 210, causing the adjacent pixels to emit light. For example, the light 320 may be a blue light.

For example, when red is implemented, the red subpixel SP2 may emit light 330b. However, light 321a and 321b may leak to adjacent pixels due to the light guide effect of the light 320 output from the light emitting element 210 of the red subpixel SP2, and thus the blue subpixel SP1 and the green subpixel SP3, which are adjacent pixels, may emit light 330a and 330c. FIG. 3B is a view illustrating a light emission defect due to light leakage to the blue subpixel SP1 and the green subpixel SP3, which are adjacent pixels, when the red subpixel SP2 is rendered to actually emit light.

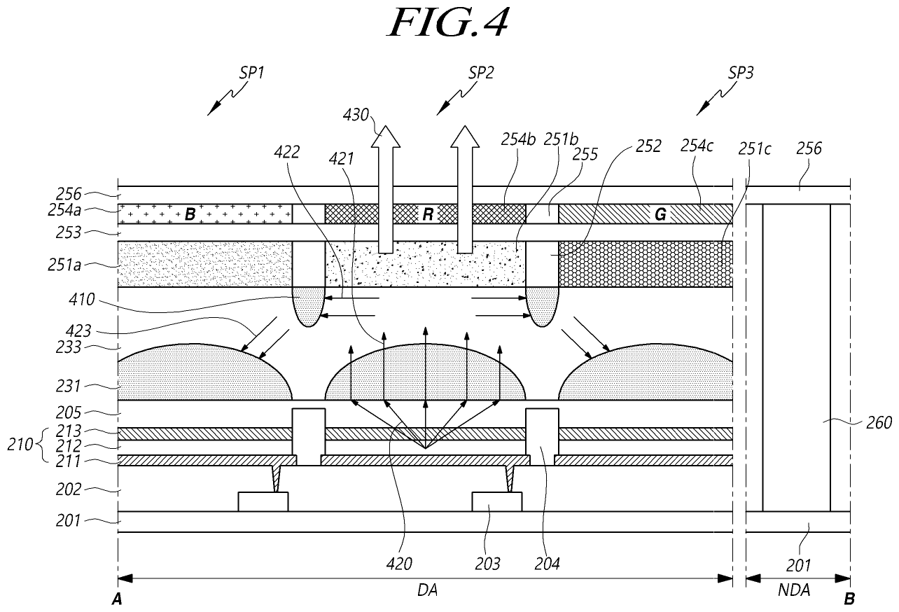

FIGS. 4 to 7 are cross-sectional views taken along line A-B of FIG. 1 to which another structure according to embodiments of the present disclosure applies. What is identical or similar to those described in connection with FIGS. 1 to 3B may be omitted or briefly described below.

FIG. 4 illustrates another example of a display device according to embodiments of the present disclosure, and a third lens 410 may be disposed on the second bank 252.

Referring to FIG. 4, a third lens part including a third lens 410 disposed on the second bank 252 toward the first bank 204 may be included.

The third lens 410 may be a low-refractive lens having a refractive index of 1.5 or less. The refractive index of the third lens 410 may be the same as the refractive index of the first lens 231.

The refractive index of the first lens 231 and the refractive index of the third lens 410 may be smaller than the refractive index of the high-refractive layer 233.

The refractive index of the first lens 231 and the refractive index of the third lens 410 may be the same, and the refractive index of the first lens 231 and the refractive index of the third lens 410 may be smaller than the refractive index of the high-refractive layer 233.

The third lens 410 may include a low-refractive material. The third lens 410 may include the same material as the first lens 231. For example, the third lens 410 may include an organic material such as an acryl resin, an epoxy resin, a phenolic resin, a polyamide resin, a polyimide resin, polyacrylate, or the like.

The third lens 410 may have a convex lens shape.

The third lens 410 may be manufactured by dropping a material containing a low-refractive material on the second bank 252 using an inkjet process and then curing the material. Further, the third lens 410 may be manufactured through an etching process using a mask by coating the second bank 252 with a low-refractive material and curing the low-refractive material.

Referring to FIG. 4, the light 420 emitted from the red subpixel SP2 may travel in a straight line while passing through the first lens 231 and may be incident on the light conversion layer 251b. In this case, the light 421 emitted to the adjacent subpixel may be totally reflected or refracted at the boundary between the high-refractive layer 233 and the low-refractive third lens 410, and the so-redirected light 423 may be directed to the first lens 231, blocking the light directed to the adjacent pixel on the side.

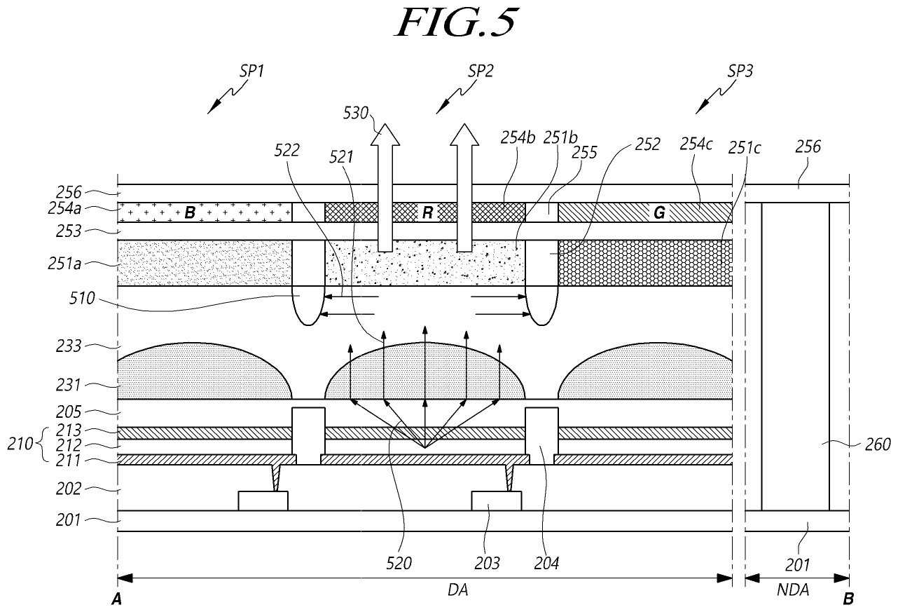

FIG. 5 illustrates another example of a display device according to embodiments of the present disclosure, and a light absorbing part 510 which is an extension of the second bank 252 may be disposed.

The light absorbing part 510 may be disposed to extend from the upper surface of the second bank 252 toward the first bank 204. The light absorbing part 510 may be integrally formed with the second bank 252.

The light absorbing part 510 may include the same material as the second bank 252. For example, the light absorbing part 510 may be an organic insulation material, and may be formed of polyimide, acryl, or benzocyclobutene (BCB)-based resin, but is not limited thereto.

The light absorbing part 510 may be formed to be greater in thickness than the light conversion layer 251a, 251b, and 251c when the second bank 252 is formed.

Referring to FIG. 5, the light 520 emitted from the red subpixel SP2 may travel in a straight line (e.g., light 521) while passing through the first lens 231 and may be incident on the light conversion layer 251b. In this case, the light 522 emitted to the adjacent subpixel may be absorbed by the light absorbing part 510 disposed on the second bank 252 to block light directed to the adjacent pixel on the side.

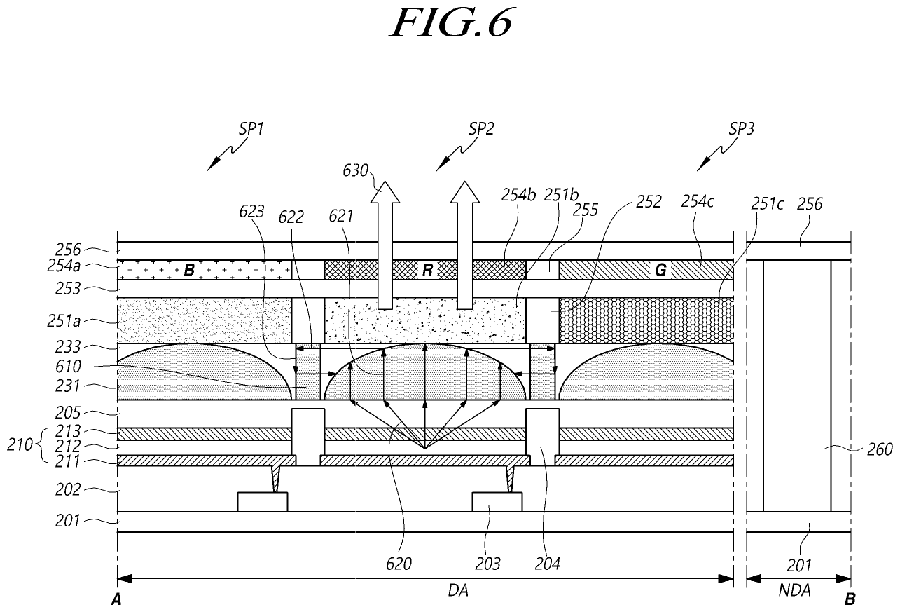

FIG. 6 illustrates another example of a display device according to embodiments of the present disclosure, and a barrier rib part 610 including a barrier rib 623 extending from the encapsulation layer 205 to the second bank 252 to overlap the second bank 252 may be disposed.

Referring to FIG. 6, the barrier rib 623 may be disposed to extend from the encapsulation layer 205 to the second bank 252. Further, the upper surface of the first lens 231 may be disposed to contact the light conversion layer 251a, 251b, and 251c.

The barrier rib 623 included in the barrier rib part 610 may be a low-refractive barrier rib having a refractive index of 1.5 or less. The refractive index of the barrier rib 623 may be the same as the refractive index of the first lens 231.

The refractive index of the barrier rib 623 and the refractive index of the first lens 231 may be smaller than the refractive index of the high-refractive layer 233.

The refractive index of the barrier rib 623 and the refractive index of the first lens 231 may be the same, and the refractive index of the barrier rib 623 and the refractive index of the first lens 231 may be smaller than the refractive index of the high-refractive layer 233.

The barrier rib 623 may include a low-refractive material. The barrier rib 623 may include the same material as the first lens 231. For example, the barrier rib 623 may include an organic material such as an acryl resin, an epoxy resin, a phenolic resin, a polyamide resin, a polyimide resin, polyacrylate, or the like.

The barrier rib 623 may be manufactured through an etching process together with the first lens 231 using a mask by coating a low-refractive material on the encapsulation layer 205 and curing the low-refractive material. A high-refractive layer 233 may be formed by depositing a high-refractive material on the encapsulation layer 205 and the first lens 231. The first substrate 201 including the first lens 231, the high-refractive layer 233, and the barrier rib 623, and the second substrate 256 including the light conversion layer 251a, 251b, and 251c and the color filter layer 254a, 254b, and 254c manufactured in a separate process may be bonded to each other.

Referring to FIG. 6, the light 620 emitted from the red subpixel SP2 may travel in a straight line (e.g., light 621) while passing through the first lens 231 and may be incident on the light conversion layer 251b. In this case, the light 622 emitted to the adjacent subpixel may be totally reflected while passing through the high-refractive layer 233 and the low-refractive barrier rib 623, and may be directed to the first lens 231, blocking the light directed to the adjacent pixel on the side.

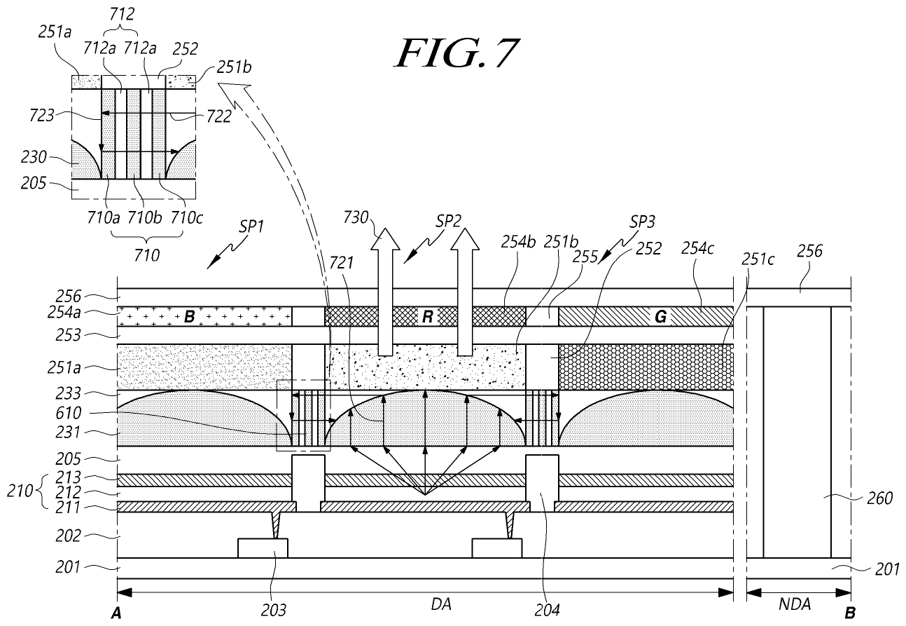

FIG. 7 illustrates another example of a display device according to embodiments of the present disclosure, and the display device may include a barrier rib part 610 in which a first barrier rib 710 including a low-refractive material and a second barrier rib 712 including a high-refractive material are alternately disposed.

Referring to FIG. 7, in the barrier rib part 610, the first barrier rib 710 and the second barrier rib 712 may be disposed to extend from the encapsulation layer 205 to the second bank 252. In other words, two opposite ends of each of the first barrier rib 710 and the second barrier rib 712 may contact the encapsulation layer 205 and the second bank 252, respectively.

The first barrier rib 710 may be a low-refractive barrier rib having a refractive index of 1.5 or less. The refractive index of the first barrier rib 710 may be the same as the refractive index of the first lens 231.

The refractive index of the first barrier rib 710 and the refractive index of the first lens 231 may be smaller than the refractive index of the high-refractive layer 233.

The refractive index of the first barrier rib 710 and the refractive index of the first lens 231 may be the same, and the refractive index of the first barrier rib 710 and the refractive index of the first lens 231 may be smaller than the refractive index of the high-refractive layer 233.

The first barrier rib 710 may include a low-refractive material. The first barrier rib 710 may include the same material as the first lens 231. For example, the first barrier rib 710 may include an organic material such as an acryl resin, an epoxy resin, a phenolic resin, a polyamide resin, a polyimide resin, polyacrylate, or the like.

The second barrier rib 712 may be a high-refractive barrier rib having a refractive index of 1.8 or more. The refractive index of the second barrier rib 712 may be the same as the refractive index of the high-refractive layer 233.

The second barrier rib 712 may include a high-refractive material. For example, the second barrier rib 712 may include an inorganic material such as silicon nitride (SiNx), silicon oxide (SiOx), silicon oxynitride (SiOxNy), or the like.

The first barrier rib 710 may be manufactured through an etching process together with the first lens 231 using a mask by coating a low-refractive material on the encapsulation layer 205 and curing the low-refractive material. The first barrier ribs 710a, 710b, and 701c may be manufactured through an etching process together with the first lens 231 using a mask by coating the encapsulation layer 205 with a low-refractive material and curing the low-refractive material. After curing the low-refractive material coated on the encapsulation layer 205, the first barrier ribs 710a, 710b, and 701c may be manufactured through an etching process together with the first lens 231 using a mask having an openings corresponding to the first barrier ribs 710a, 710b, and 701c. A high-refractive material may be deposited on the encapsulation layer 205 and the first lens 231, and the second barrier ribs 712a and 712b may be formed by stacking the high-refractive material between the first barrier ribs 710a, 710b, and 701c. The first substrate 201 including the first lens 231, the high-refractive layer 233, the first barrier rib 710, and the second barrier rib 712, and the second substrate 256 including the light conversion layer 251a, 251b, and 251c and the color filter layer 254a, 254b, and 254c manufactured in a separate process may be bonded to each other.

Referring to FIG. 7, the light emitted from the red subpixel SP2 may travel in a straight line (e.g., light 721) while passing through the first lens 231 and may be incident on the light conversion layer 251b. In this case, the light 722 emitted to the adjacent subpixel may be totally reflected (as indicated by light 723 in FIG. 7) while sequentially passing through the low-refractive first barrier rib 710 and the high-refractive second barrier rib 712 and be directed to the first lens 231, blocking the light directed to the adjacent pixel on the side.

Embodiments of the present disclosure described above are briefly described below.

A display device according to embodiments of the present disclosure may comprise a first substrate including at least one of red, green, and blue subpixels, a light emitting element including a first electrode disposed on the first substrate, a light emitting layer disposed on the first electrode, and a second electrode disposed on the light emitting layer, a first bank having an opening exposing at least a portion of the first electrode, a first lens part disposed on the second electrode and having a first lens including a low-refractive material corresponding to the opening, a high-refractive layer disposed on the first bank and the first lens part and including a high-refractive material, a light conversion layer disposed on the high-refractive layer and including a quantum dot converting light of a color corresponding to each of the red, green, and blue subpixels, and a color filter layer disposed on the light conversion layer and having a color corresponding to each of the red, green, and blue subpixels.

The display device according to embodiments of the disclosure may further comprise a second lens part including a second lens including the low-refractive material. The second lens part may face the first lens part and be disposed under the light conversion layer.

In the display device according to embodiments of the present disclosure, the first lens and the second lens may have a convex lens shape. A convex surface of the first lens and a convex surface of the second lens may contact each other.

In the display device according to embodiments of the present disclosure, the first lens and the second lens may have the same refractive index. The refractive indexes of the first lens and the second lens may be smaller than a refractive index of the high-refractive layer.

In the display device according to embodiments of the present disclosure, the light conversion layers for the red, green, and blue subpixels may be partitioned by a second bank. The second bank may be disposed to overlap the first bank.

In the display device according to embodiments of the present disclosure, the second bank may include a light absorbing part disposed to extend toward the first bank.

The display device according to embodiments of the present disclosure may further comprise a third lens part including a third lens including the low-refractive material on the second bank toward the first bank.

In the display device according to embodiments of the present disclosure, the third lens may have a convex lens shape and have the same refractive index as a refractive index of the first lens.

In the display device according to embodiments of the present disclosure, an upper surface of the first lens part may contact the light conversion layer.

The display device according to embodiments of the present disclosure may further comprise an encapsulation layer between the light emitting element and the first lens part. A barrier rib part may be disposed on the encapsulation layer to extend to the second bank to overlap the second bank.

In the display device according to embodiments of the present disclosure, the barrier rib part may include a barrier rib including the low-refractive material.

In the display device according to embodiments of the present disclosure, in the barrier rib part, a first barrier rib including the low-refractive material and a second barrier rib including the high-refractive material may be alternately disposed.

In the display device according to embodiments of the present disclosure, a quantum dot barrier layer may be disposed between the light conversion layer and the color filter layer.

The display device according to embodiments of the present disclosure may further comprise a second substrate on the color filter layer. The first substrate and the second substrate may be divided into a display area and a non-display area. A sealing member may be disposed between the first substrate and the second substrate corresponding to the non-display area.

According to embodiments of the present disclosure, there may be provided a display device capable of blocking light propagation to the adjacent pixel.

According to embodiments of the present disclosure, there may be provided a display device capable of enhancing light extraction efficiency by blocking light propagation to the adjacent pixel.

According to embodiments of the present disclosure, there may be provided a display device capable of low power consumption by blocking light propagation to the adjacent pixel.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate including at least one of red, green, and blue subpixels;
a light emitting element including a first electrode disposed on the first substrate, a light emitting layer disposed on the first electrode, and a second electrode disposed on the light emitting layer;
a first bank having an opening exposing at least a portion of the first electrode;
a first lens part disposed on the second electrode, the first lens part having a first lens including a low-refractive material corresponding to the opening;
a high-refractive layer disposed on the first bank and the first lens part, the high-refractive layer including a high-refractive material;
a light conversion layer disposed on the high-refractive layer, the light conversion layer including a quantum dot converting light of a color corresponding to each of the red, green, and blue subpixels; and
a color filter layer disposed on the light conversion layer, the color filter layer having a color corresponding to each of the red, green, and blue subpixels.

2. The display device of claim 1, further comprising a second lens part including a second lens including the low-refractive material,
wherein the second lens part faces the first lens part and is disposed under the light conversion layer.

3. The display device of claim 2, wherein the first lens and the second lens have a convex lens shape, and
wherein a convex surface of the first lens and a convex surface of the second lens contact each other.

4. The display device of claim 2, wherein the first lens and the second lens have the same refractive index, and
wherein the refractive indexes of the first lens and the second lens are smaller than a refractive index of the high-refractive layer.

5. The display device of claim 1, wherein the light conversion layers for the red, green, and blue subpixels are partitioned by a second bank, and
wherein the second bank is disposed to overlap the first bank.

6. The display device of claim 5, wherein the second bank includes a light absorbing part disposed to extend toward the first bank.

7. The display device of claim 5, further comprising a third lens part including a third lens including the low-refractive material on the second bank toward the first bank.

8. The display device of claim 7, wherein the third lens has a convex lens shape and has the same refractive index as a refractive index of the first lens.

9. The display device of claim 5, wherein an upper surface of the first lens part contacts the light conversion layer.

10. The display device of claim 9, further comprising:
an encapsulation layer between the light emitting element and the first lens part; and
a barrier rib part disposed on the encapsulation layer to extend to the second bank to overlap the second bank.

11. The display device of claim 10, wherein the barrier rib part includes a barrier rib including the low-refractive material.

12. The display device of claim 10, wherein in the barrier rib part, a first barrier rib including the low-refractive material and a second barrier rib including the high-refractive material are alternately disposed.

13. The display device of claim 1, wherein a quantum dot barrier layer is disposed between the light conversion layer and the color filter layer.

14. The display device of claim 1, further comprising a second substrate on the color filter layer,
wherein the first substrate and the second substrate are divided into a display area and a non-display area, and
wherein a sealing member is disposed between the first substrate and the second substrate corresponding to the non-display area.

15. The display device of claim 1, wherein the high-refractive layer has a refractive index of 1.8 or more.

16. The display device of claim 1, wherein the high-refractive layer includes an inorganic material including any one of silicon nitride, silicon oxide, or silicon oxynitride.

17. The display device of claim 1, wherein the low-refractive material has a refractive index of 1.5 or less.

18. The display device of claim 1, wherein the low-refractive material includes an organic material including any one of acryl resin, epoxy resin, phenolic resin, polyamide resin, polyimide resin, or polyacrylate.
